(19) United States
(12) Patent Application Publication
(10) Pub. No.: US 2010/0084712 A1
(43) Pub. Date: Apr. 8, 2010

(54) MULTIPLE SPACER AND CARBON IMPLANT COMPRISING PROCESS AND SEMICONDUCTOR DEVICES THEREFROM

(75) Inventor: Puneet Kohli, Dallas, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 12/245,470

(22) Filed: Oct. 3, 2008

(51) Int. Cl. H01L 27/088; H01L 21/8238

(52) U.S. Cl. 257/368; 438/231; 257/E27.06

(57) ABSTRACT

An integrated circuit (IC) and multi-spacer methods for forming the same includes at least one metal-oxide semiconductor (MOS) transistor including a substrate having a semiconductor surface, a gate stack formed in or on the surface comprising a gate electrode on a gate dielectric, wherein a channel region is located in said semiconductor surface below the gate dielectric. A spacer structure is on the sidewalls of the gate stack, wherein the spacer structure includes a first spacer and a second spacer positioned outward from the first spacer. A source and a drain region are on opposing sides of the gate stack each having a maximum C concentration≧1×10¹⁷ cm⁻³. Source and drain extension (LDD) regions are positioned between the source and drain and the channel region. A maximum C concentration in the first spacer is ≧20% greater than a maximum C concentration in the second spacer which reflects C being substantially removed from being close to the LDD/channel junction, thus reducing gate-edge diode leakage (GDL) while still maintaining good short-channel effects (SCE).

### FIELD OF INVENTION

Embodiments of the present invention relate to methods for manufacturing semiconductor devices including carbon (C) implants and semiconductor devices and integrated circuits (ICs) therefrom.

### BACKGROUND

It is well known that dimensions of transistors in integrated circuits (ICs) are shrinking with each new generation of fabrication technology, as articulated in Moore's Law. Source and drain elements of MOS transistors are shrinking in both lateral and vertical directions, requiring tighter control over dopant distributions to maintain transistor performance parameters such as on-state drive current and off-state leakage current. Source and drain elements of MOS transistors typically include two sub-elements: a shallow, lightly doped region, commonly known as the lightly doped drain (LDD) closest to the MOS transistor channel region, and a deeper, heavily doped region commonly known as the source/drain (SD), which is typically laterally separated from the MOS transistor channel region.

The LDD and SD sub-elements are formed separately. LDD and SD sub-elements of MOS transistors are generally formed by ion implanting a first-type dopant into an opposite- type region of the surface of a silicon wafer. In addition, dopants may be ion implanted at an angle during the LDD formation process, commonly known as a halo implant, to reduce the short channel effect.

C may be implanted into the NLDD regions to reduce the diffusion of P and B atoms during the subsequent high temperature anneal. C can also assist with Indium (In) activation in processes that include In implants (e.g. pocket or Vt implants). C is conventionally implanted after formation of the gate electrode as part of the LDD processing. Separate implants may be used for PMOS and NMOS transistors.

It is common for ICs to have two types of MOS transistors: a first type and a second type that has a higher Vt as compared to the first type. For example, in the case of NMOS, high threshold NMOS is typically formed by the same process sequence as the core NMOS, with the exception that high Vt NMOS transistors receive an extra dose of p-type dopants in the channel region immediately under the gate to increase Vt. High Vt NMOS has lower off-state leakage current than core NMOS. However, gate-edge diode leakage (GDL) from the reverse biased junction between the drain and the p-type channel region is a dominant source of off-state leakage current in high threshold NMOS transistors, which is undesirable for IC performance. Accordingly, there is a need for new processes and MOS device architectures that reduce GDL, while at the same time still achieving relative good short-channel effects (SCE).

### SUMMARY

This Summary is provided to comply with 37 C.F.R. §1.73, presenting a summary of the invention to briefly indicate the nature and substance of the invention. It is submitted with the understanding that it will not be used to interpret or limit the scope or meaning of the claims.

Embodiments of the present invention describe methods and resulting devices and integrate circuits (ICs) therefrom that are based on selective C implantation that removes or at least reduces the concentration of C that is proximate to the LDD/channel junction to improve MOS device properties, which has been found to reduce GDL while still generally achieving good SCE.

The present Inventor has recognized that despite its benefits, C implantation resulting in a significant C concentration reaching the NLDD or PLDD depletion regions can result in an increase in GDL, particularly when the C is directly implanted into the NLDD or I)LDD depletion region of the device, specifically at the junction that exists between the LDD and the channel region of NMOS or PMOS transistors.

Embodiments of the present invention include selective C implantation that removes or at least reduces the C implanted from resulting in any significant C concentration being close to the LDD/channel junction for one or both NMOS and PMOS transistors. Limiting the C implant from entering the semiconductor region under the offset spacer and thus away from the LDD/channel junction has been found by the present Inventor to achieve low GDL while still achieving good SCE performance by maintaining the benefit of C suppressing diffusion of dopants in the remaining portion of the LDD region and the later formed SD regions.

### BRIEF DESCRIPTION OF THE DRAWINGS

FIGS. 1A through 1F are cross-sectional views schematically illustrating steps in a dual spacer method for forming a semiconductor device, according to an embodiment of the invention.

FIG. 2 is a cross sectional view of an integrated circuit (IC) including a PMOS and an NMOS transistor, with both the PMOS and NMOS transistors having dual spacers formed according to an embodiment of the invention to provide C in the LDD regions but minimized at the LDD/channel junctions, according to an embodiment of the invention.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

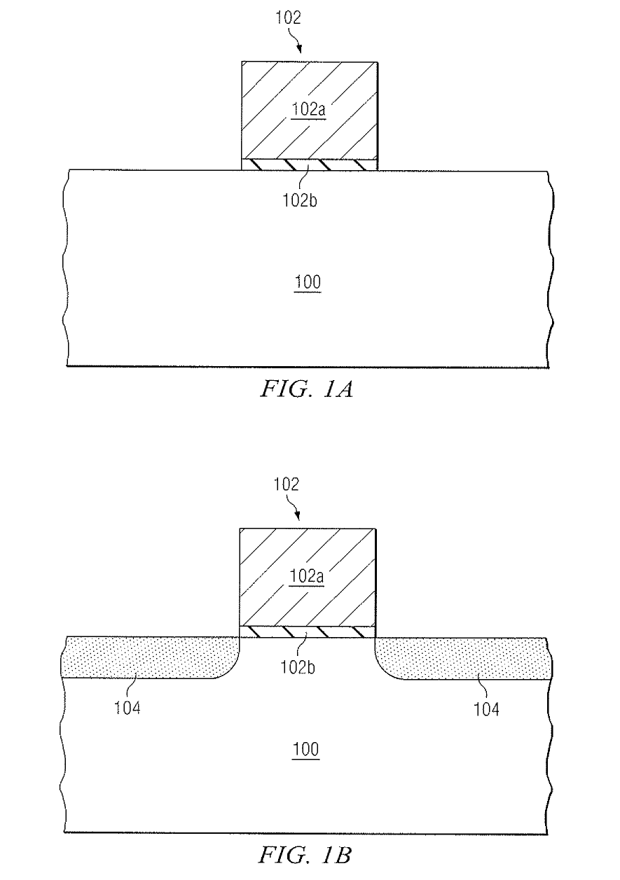

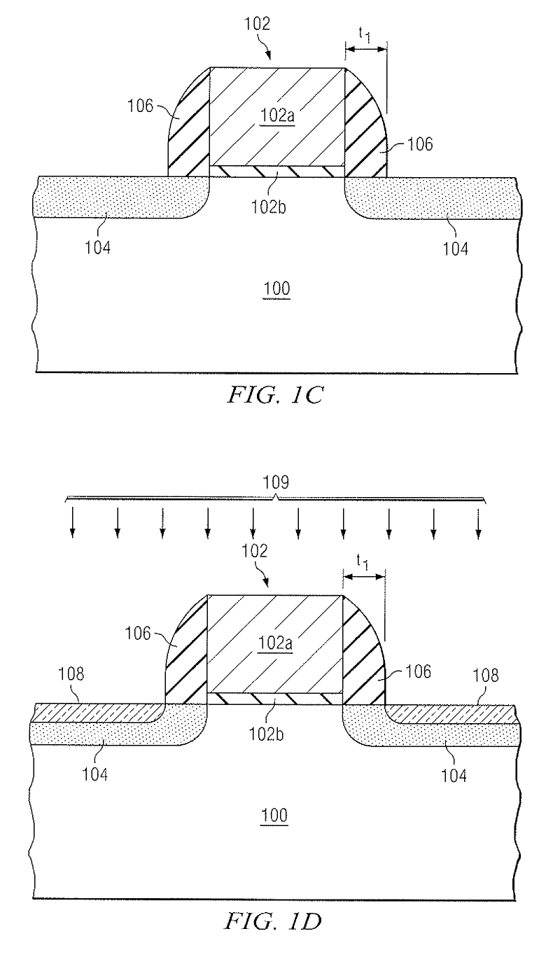

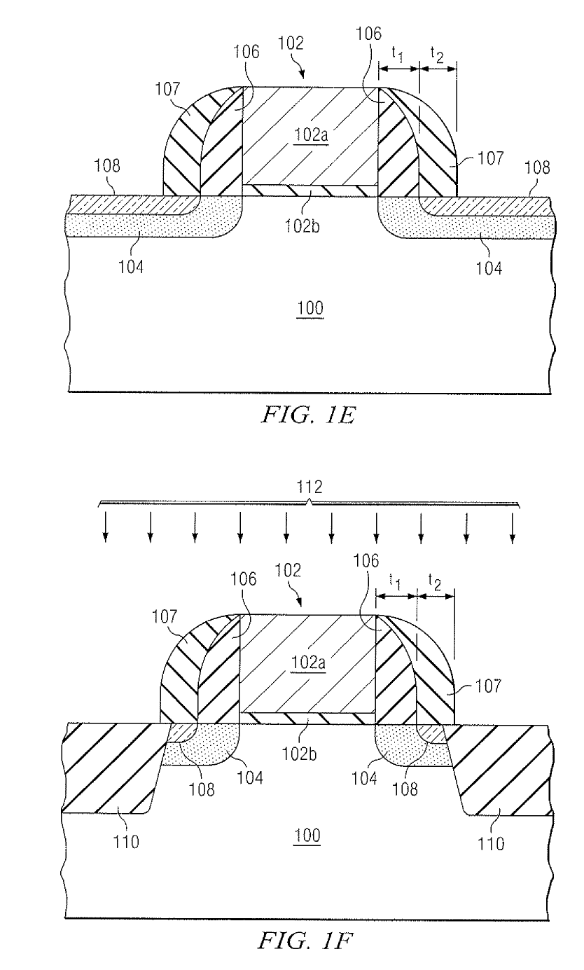

FIGS. 1A through 1F are cross-sectional views schematically illustrating a dual spacer C LDD co-implant method for forming MOS transistors according to an embodiment of the invention. Embodiments of the invention minimize the concentration of implanted C that reaches the LDD/channel junction in the completed IC to improve device properties, including a reduction in GDL. Although generally described relative to NMOS transistors, embodiments of the invention also apply to PMOS transistors. Embodiments of the invention can also be used to form gated diodes as well, which as known in the art comprise MOS transistors that have their sources and drains shorted together.

As shown in FIG. 1A, a gate stack 102 comprising a gate electrode 102(a) and a gate dielectric layer 102(b) is formed on a substrate 100 that provides a semiconducting surface. The method for forming the gate structure 102 can, for example, comprise the steps of forming a dielectric layer and a gate electrode layer over the substrate 100 sequentially and then patterning the gate electrode layer into the gate structure 102 by using a photolithography process and etching process. The dielectric layer 102(b) can be, for example but not limited to, silicon oxide, or a high-k dielectric, such as silicon nitride, or silicon-oxy nitride (SiON), or a gate dielectric having a k-value>10. The gate electrode layer 102(a) can be, for example, polysilicon.

Then, as shown in FIG. 11B, a lightly doped drain (LDD) region 104 is formed in the substrate 100 adjacent to the gate structure 102. The method for forming the LDD region 104 generally comprises a first and a second ion implantation process to implant dopants, comprising P dopants in the first implantation process for PMOS transistors and then N Dopants for the second implantation process for NMOS transistors into the surface of the substrate 100 using the gate stack 102 as an implant mask.

As shown in FIG. 1C, a first spacer 106 (also sometimes referred to herein as an offset spacer) 106 is formed on the sidewalls of the gate stack 102. The method for forming the first spacer 106 can comprise the steps of forming a spacer material layer over the substrate 100 and then performing an anisotropic etching process. The spacer deposition process can be a low temperature process, such as a plasma enhanced CVD process at a temperature <550° C., such as <500° C., to limit transient diffusion of the dopant in LDD region 104 during the spacer deposition process. The spacer material layer can be, for example but not limited to, silicon oxide, silicon nitride or SiON. The thickness (measured in the lateral dimension) of the spacer is shown as t₁ in FIG. 1C and is generally in a range from 50 to 1,500 Angstroms.

As shown in FIG. 1D, a C implantation process 109 is performed to implant C into the surface of substrate 100 to form region 108 within LDD region 104. Implant process 109 can be a single blanket maskless process for implanting both NMOS and PMOS transistors. In another embodiment, the implant process includes a masking step comprising an implant mask (e.g. using a resist), to either allow different C implant parameters (e.g. dose), or one of the device types to not receive the C implant (e.g. mask only PMOS transistors).

The implantation dosage for the C implantation process 109 is generally about 1×10¹³ to about 5×10¹⁵ atom/cm² and the implantation energy of the C implantation process is generally about 0.1 to about 40 KeV, such as 1 to 30 Kev. The implant angle is generally <45 degrees relative to the wafer surface normal, such as a conventional 7 degree angle or a 0 degree angle. Angled nearly normal to the surface of the substrate 100 results in minimizing the lateral spreading of the C implant by allowing the first spacer 106 to mask the implanted C from entering the surface region of substrate 100 under the first spacer 106 and the channel region under the gate stack 102. The masking function provided by first spacer 106 results in a significant dose of implanted C being received by first spacer 106 from the C implantation process 109. In a typical embodiment, the maximum C concentration in the first spacer 106 in the completed device is between 1×10¹⁶ to 1×10²¹ cm⁻³, and is generally between 1×10¹⁸ to 1×10²⁰cm⁻³.

Due to masking provided by first spacer 106, as implanted, the C implanted portion is laterally recessed as shown in FIG. 1D a distance of about t₁ from the lateral extent of LDD region 104. Limiting the C implant from entering the semiconductor under the offset spacer 106 and thus away from the LDD/channel junction has been found by the Present Inventor to achieve low GDL by keeping C away from the junction depletion region of the final device while still achieving good SCE performance by maintaining the benefit of C suppressing diffusion of dopants in the remaining portion of the LDD region 104 and the later formed SD regions 110 (described below).

As shown in FIG. 1E, a second spacer 107, also referred to herein as a sidewall spacer, is formed on the sidewall of the gate stack 102 alongside first spacer 106. In one embodiment, the first spacer 106 comprises silicon nitride and the second spacer 107 comprises silicon oxide. In another embodiment (not shown), the first spacer 106 can be selectively removed before forming the second spacer 107. The thickness of second spacer 107 is shown as t₂. As shown, the total spacer thickness is t₁+t₂. As with the first spacer 106, the method for forming the second spacer 107 can comprise the steps of forming (e.g. depositing) a spacer material layer over the substrate 100 and then performing an anisotropic etching process (e.g. RIE).

Then, as shown in FIG. 1F, SD regions 110 are formed by implantation process 112 into the substrate 100, wherein the resulting SD regions 110 are shown after a short high temperature activation/anneal, for example, a rapid thermal annealing process(e.g. a spike anneal) at a temperature around 950° C. In FIG. 1F, spacers 106 and 107 and the gate stack 102 provide implant masks, wherein the conductive type of the dopants for forming the source/drain region 110 is as same as that for forming the source/drain extension region 104.

In the flow described relative to FIGS. 1A-F, C is implanted into first spacer 106 but not into the second spacer 107. Assuming there are no other C implants subsequent to formation of spacer 107, the C maximum concentration in the first spacer as described above is in the completed device is between 1×10¹⁶ cm⁻³ to 1×10²¹ cm⁻³, and is generally between 1×10¹⁸ cm⁻³ to 1×10²⁰ cm⁻³, while the maximum C concentration in the second spacer 107 or any subsequent spacers in the completed device is <1×10¹⁶ cm⁻³.

More generically, including the case where C is also implanted subsequent to the formation of the second spacer 107 (e.g. in addition to the C implant after formation of first spacer 106, C is implanted after the second spacer 107, third spacer, etc.), the maximum C concentration in the first spacer 106 is ≧20% than the maximum C concentration in any spacer(s) formed after the first spacer 106.

As shown in FIG. 1F, the SD regions 110 are laterally recessed from the lateral extent of the C implanted region 108 by nearly the thickness of the second spacer 107 (t₂). Although not shown, a pre-amorphous implantation process can be selectively performed in the SD regions 110.

Conventional processing can generally be used to complete fabrication of the semiconductor devices, such metal silicide layer formation on the gate electrode 102(a) in the case of polysilicon and on the SD regions 110, conventional BEOL processing including multi-layer damascene metallization and passivation. The metal silicide layer can be, for example, made of tungsten silicide titanium silicide, cobalt silicide, molybdenum silicide, nickel silicide, palladium silicide, platinum silicide or other well known material. The method for forming the metal silicide layer can be, for example, a self-aligned metal silicide process.

In one embodiment, the processing includes replacement gate processing. Replacement gate processing allows metal gates to be provided for one or both PMOS and NMOS transistors.

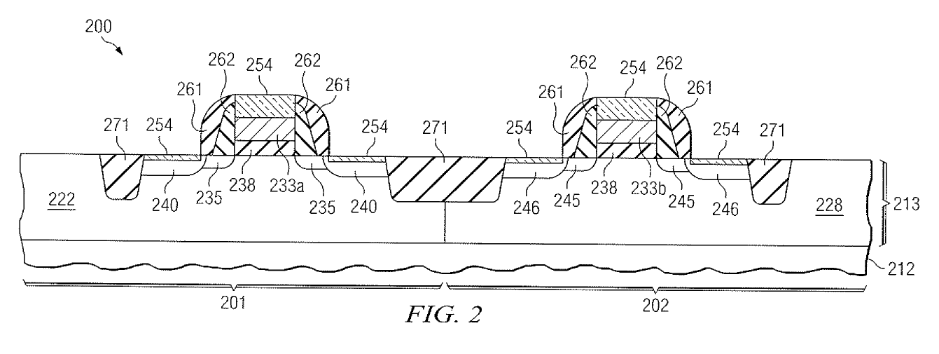

FIG. 2 is a cross sectional view of an IC 200 including a PMOS device 201 and an NMOS device 202, with both the PMOS and NMOS transistors having dual spacers 261, 262 formed according to an embodiment of the invention to provide significant C concentrations in the LDD regions but minimized at the LDD/channel junctions, according to an embodiment of the invention. IC 200 comprises a substrate 212 having a semiconductor surface 213. Trench isolation 271 is shown. An Nwell 222 and a Pwell 228 are formed in the semiconductor surface 213. A gate stack for both PMOS device 201 and an NMOS device 202 is formed in or on the surface 213 and comprises gate electrode 233a for PMOS (egg. P+ doped) and 233b for NMOS (e.g. N+ doped), collectively referred to as gate electrode 233. A silicide layer 254 is shown on gate electrode 233 and a gate dielectric 238 is shown beneath the gate electrode 233, wherein a channel region is located in the semiconductor surface below the gate dielectric 238 for both PMOS device 201 and an NMOS device 202. A spacer structure is on both sidewalls of the gate stack 254/233/238, wherein the spacer structure comprises a first spacer 262 and a second spacer 261 positioned outward from the first spacer 262.

PMOS device 201 includes SD regions 240 positioned on opposing sides of said gate stack 254/233a/238 having a maximum C concentration≧1×10¹⁷ cm⁻³. PMOS device 201 also includes SD extension (LDD) regions 235 positioned between the SD regions 240 and the channel region of PMOS device 201. NMOS device 202 includes SD regions 246 positioned on opposing sides of the gate stack 254/233b/238 having a maximum C concentration≧1×10¹⁷ cm⁻³. Although both PMOS device 201 and NMOS device 202 are shown having significant C concentrations in their SD regions, in other embodiments of the invention only one of PMOS device 201 and NMOS device 202 has significant C concentrations in their SD regions. NMOS device 202 also includes SD extension (LDD) regions 245 positioned between the SD regions 246 and the channel region of NMOS device 202.

A maximum C concentration in the first spacer 262 is ≧20% greater than a maximum C concentration in the second spacer 261. As described above first spacer 262 received the additional C concentration compared to second spacer 261 due to its C implant masking function which removes C from being close to the LDD/channel junction, thus reducing GDI. while still maintaining good SCE. In another embodiment, the maximum C concentration in the first spacer 262 is ≧100 times the maximum C concentration in the second spacer 261. For example, the maximum C concentration in the first spacer 262 can be between 1×10¹⁸/cm³ and 1×10²⁰/cm³, while the maximum C concentration in the second spacer 261 can be 1×10¹⁶/cm³.

The IC 200 can include a plurality of NMOS transistors 202 comprising a plurality of relatively low Vt NMOS transistors and a plurality of high relative Vt NMOS transistors, wherein the plurality of high relative Vt NMOS transistors on average have a higher p-type dopant concentration in their channel region as compared to said low relative VT NMOS transistors. The SD regions 240 for PMOS device 201 and 246 for NMOS device 202 can also include In.

Embodiments of the invention can be integrated into a variety of process flows to form a variety of devices and related IC-based products. The semiconductor substrates may include various elements therein and/or layers thereon. These can include barrier layers, other dielectric layers, device structures, active elements and passive elements including source regions, drain regions, bit lines, bases, emitters, collectors, conductive lines, conductive vias, etc. Moreover, the invention can be used in a variety of processes including bipolar, CMOS, BiCMOS and MEMS.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

I claim:

1. An integrated circuit (IC) including at least one metal-oxide semiconductor (MOS) transistor, said MOS transistor comprising:
a substrate having a semiconductor surface;
a gate stack formed in or on said surface comprising a gate electrode on a gate dielectric, wherein a channel region is located in said semiconductor surface below said gate dielectric,
a spacer structure on sidewalls of said gate stack, said spacer structure comprising a first spacer and a second spacer positioned outward from said first spacer;
a source and a drain region on opposing sides of said gate stack having a maximum C concentration≧1×10¹⁷ cm⁻³, and
source and drain extension (LDD) regions positioned between said source and said drain region and said channel region,
wherein a maximum C concentration in said first spacer is ≧20% greater than a maximum C concentration in said second spacer.

2. The IC of claim 1, wherein said maximum C concentration in said first spacer is ≧100 times said maximum C concentration in said second spacer.

3. The IC of claim 2, wherein said maximum C concentration in said first spacer is between 1×10¹⁸/cm³ and 1×10²⁰/cm³, and said maximum C concentration in the second spacer is <1×10¹⁶/cm³.

4. The IC of claim 1, wherein said first spacer and said second spacer comprise different materials.

5. The IC of claim 4, wherein said first spacer comprises silicon nitride, silicon carbide or silicon oxynitride and said second spacer comprises silicon dioxide.

6. The IC of claim 1, wherein said at least one MOS transistor comprises a plurality of relatively low Vt NMOS transistors and a plurality of high relative Vt NMOS transistors, wherein said plurality of high relative Vt NMOS transistors on average have a higher p-type dopant concentration in their channel region as compared to said low relative VT NMOS transistors.

7. The IC of claim 1, wherein said source and said drain regions include In.

8. A method for manufacturing an integrated circuit (IC) including at least one metal-oxide semiconductor (MOS) transistor, comprising:
providing a substrate having a semiconductor surface;
forming a gate stack comprising a gate electrode on a gate dielectric on said semiconductor surface, wherein a channel region is located in said silicon surface below said gate dielectric;
forming a source/drain extension (LDD) region in said substrate adjacent to the gate stack;
after forming said LDD region, forming a first spacer on sidewalls of said gate structure, said first spacer;
C implanting a plurality of C ions into said substrate after said forming said first spacer using said first spacer as an implant mask;
forming a second spacer on said sidewall of said gate structure,
forming a source/drain region in said substrate using said second spacer as an implant mask, and
completing fabrication of said MOS transistor.

9. The method of claim 8, wherein a dosage for said C implanting is from 1×10¹³/cm² to 5×10¹⁵/cm² and an implantation energy for said carbon implanting is from 1 to 30 keV.

10. The method of claim 8, wherein an implant angle for said C implanting is ≦7 degrees.

11. The method of claim 10, wherein said implant angle is 0 degrees.

12. The method of claim 8, wherein said first spacer and said second spacer comprise different materials, and said first and second spacer are non-sacrificial layers.

13. The method of claim 12, wherein said first spacer comprises silicon nitride, silicon carbide or silicon oxynitride and said second spacer comprises silicon dioxide.

14. The method of claim 8, further comprising stripping said first spacer before said forming said second spacer.

15. The method of claim 8, wherein said forming said first spacer and said forming said second spacer comprises deposition processes both having a maximum temperature <550° C.

16. The method of claim 8, wherein said IC includes at least one NMOS transistor and at least one PMOS transistor, wherein said C implanting comprises simultaneously implanting said NMOS transistor and said PMOS transistor.
